(19) United States
(12) Patent Application Publication
(10) Pub. No.: US 2025/0098480 A1
(43) Pub. Date: Mar. 20, 2025

(54) DISPLAY APPARATUS INCLUDING A CUSHION LAYER

(71) Applicant: SAMSUNG DISPLAY CO., LTD., Yongin-si (KR)

(72) Inventors: Minsun JUNG, Yongin-si (KR); Taesoo KANG, Yongin-si (KR); Jaemo CHUNG, Yongin-si (KR)

(21) Appl. No.: 18/652,974

(22) Filed: May 2, 2024

(30) Foreign Application Priority Data
Sep. 18, 2023 (KR) 10-2023-0124258

(51) Int. Cl. H10K 59/80

(52) U.S. Cl. CPC H10K 59/87

(57) ABSTRACT

A display apparatus includes: a display panel including a substrate and a display layer that is arranged on the substrate and that is configured to display images; a cover window arranged on the display panel; a protective film arranged under the display panel; and a cushion layer arranged on the protective film, wherein the cover window includes: a first cover window portion overlapping the protective film; and a second cover window portion at least partially surrounding the first cover window portion, wherein the cushion layer includes: a first cushion layer portion overlapping the protective film; and a second cushion layer portion including a grounded metal material and protruding outwards from the first cushion layer portion, and wherein the second cover window portion and the second cushion layer portion are spaced apart from each other.

### CROSS-REFERENCE TO RELATED APPLICATION

This application claims priority under 35 U.S.C. § 119 to Korean Patent Application No. 10-2023-0124258, filed on Sep. 18, 2023, in the Korean Intellectual Property Office, the disclosure of which is incorporated by reference herein in its entirety.

### TECHNICAL FIELD

One or more embodiments of the present invention relate to a display apparatus, and more particularly, to a display apparatus including a cushion layer.

### DISCUSSION OF THE RELATED ART

Mobile electronic devices have grown exponentially in popularity. Recently, in addition to small electronic devices such as mobile phones, tablet personal computers (PCs) are widely used as mobile electronic devices.

Many mobile electronic devices include a display apparatus to provide visual information such as images or video to a user. Recently, as the sizes of other components for driving a display apparatus have decreased, the area occupied by display apparatuses in electronic devices has gradually increased, and a structure that may be bent by a certain angle from a flat state may be included in electronic devices.

### SUMMARY

According to one or more embodiments of the present invention, a display apparatus includes: a display panel including a substrate and a display layer that is arranged on the substrate and that is configured to display images; a cover window arranged on the display panel; a protective film arranged under the display panel; and a cushion layer arranged on the protective film, wherein the cover window includes: a first cover window portion overlapping the protective film; and a second cover window portion at least partially surrounding the first cover window portion, wherein the cushion layer includes: a first cushion layer portion overlapping the protective film; and a second cushion layer portion including a grounded metal material and protruding outwards from the first cushion layer portion, and wherein the second cover window portion and the second cushion layer portion are spaced apart from each other.

In one or more embodiments of the present invention, a cushion opening is arranged between the second cover window portion and the second cushion layer portion.

In one or more embodiments of the present invention, at least part of the second cushion layer portion does not overlap the protective film.

In one or more embodiments of the present invention, the first cushion layer portion and the second cushion layer portion include a same material as each other.

In one or more embodiments of the present invention, the second cushion layer portion includes a copper material.

In one or more embodiments of the present invention, the second cushion layer portion is provided in a plurality.

In one or more embodiments of the present invention, at least two of the plurality of second cushion layer portions have different shapes from each other.

In one or more embodiments of the present invention, on a plane, the second cushion layer portion has a rectangular shape.

In one or more embodiments of the present invention, on a plane, the second cushion layer portion has a triangular shape or part of an oval shape.

In one or more embodiments of the present invention, the second cushion layer portion surrounds at least a part of the first cushion layer portion.

According to one or more embodiments of the present invention, a display apparatus includes: a display panel including a substrate and a display layer that is arranged on the substrate and that is configured to display images; a cover window arranged on the display panel; a protective film arranged under the display panel; and a cushion layer arranged under the protective film, wherein the cover window includes: a first cover window portion overlapping the protective film; and a second cover window portion at least partially surrounding the first cover window portion, wherein the cushion layer includes: a first cushion layer portion overlapping the protective film; and a second cushion layer portion including a grounded metal material and protruding outwards from the first cushion layer portion, and wherein at least part of the second cushion layer portion does not overlap the protective film.

In one or more embodiments of the present invention, the second cover window portion and the second cushion layer portion are spaced apart from each other.

In one or more embodiments of the present invention, a cushion opening is arranged between the second cover window portion and the second cushion layer portion.

In one or more embodiments of the present invention, the first cushion layer portion and the second cushion layer portion include a same material as each other.

In one or more embodiments of the present invention, the second cushion layer portion includes a copper material.

In one or more embodiments of the present invention, the second cushion layer portion is provided in a plurality.

In one or more embodiments of the present invention, at least two of the plurality of second cushion layer portions have different shapes from each other.

In one or more embodiments of the present invention, on a plane, the second cushion layer portion has a rectangular shape.

In one or more embodiments of the present invention, on a plane, the second cushion layer portion has a triangular shape or part of an oval shape.

In one or more embodiments of the present invention, the second cushion layer portion surrounds at least a part of the first cushion layer portion.

### BRIEF DESCRIPTION OF THE DRAWINGS

The above and other aspects, features of embodiments of the present invention will be more apparent by describing in detail embodiments thereof, with reference to the accompanying drawings, in which:

FIG. 1 is a plan view schematically illustrating a display apparatus according to an embodiment of the present invention;

FIG. 2 is rear view schematically illustrating part of a display apparatus according to an embodiment of the present invention;

FIGS. 3, 4 and 5 are cross-sectional views schematically illustrating part of a display apparatus according to an embodiment of the present invention;

FIG. 6 is a cross-sectional view schematically illustrating a display apparatus according to an embodiment of the present invention;

FIG. 7 is a circuit diagram of a pixel of a display apparatus according to an embodiment of the present invention; and

FIGS. 8, 9, 10, and 11 are rear views schematically illustrating a display apparatus according to an embodiment of the present invention.

### DETAILED DESCRIPTION OF THE EMBODIMENTS

Exemplary embodiments of the present invention will now be described more fully with reference to the accompanying drawings. It is to be understood that the present invention may be embodied in different forms and thus should not be construed as being limited to the embodiments set forth herein. It is to be understood that like reference numerals may refer to like elements throughout the specification, and thus, redundant descriptions may be omitted. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the spirit and scope of the present invention.

It will be understood that the singular expression includes a plurality of expressions unless the context is clearly different.

It will be understood that when an element or layer is referred to as being “on” another element or layer, the element or layer may be directly on another element or layer or intervening elements or layers.

In the drawings, various thicknesses, lengths, and angles are shown and while the arrangement shown does indeed represent an embodiment of the present invention, it is to be understood that modifications of the various thicknesses, lengths, and angles may be possible within the spirit and scope of the present invention and the present invention is not necessarily limited to the particular thicknesses, lengths, and angles shown.

It is to be understood that the x-axis, the y-axis, and the z-axis are not limited to three axes on a Cartesian coordinate system, and may be interpreted in a broad sense including the same. For example, the x-axis, the y-axis, and the z-axis may be perpendicular to each other, but may refer to different directions that are not orthogonal to each other.

It is to be understood that in the case where some embodiments may be implemented differently, a specific process order may be performed differently from the order described. For example, two processes described in succession may be performed at substantially the same time, or in an order opposite to a described order.

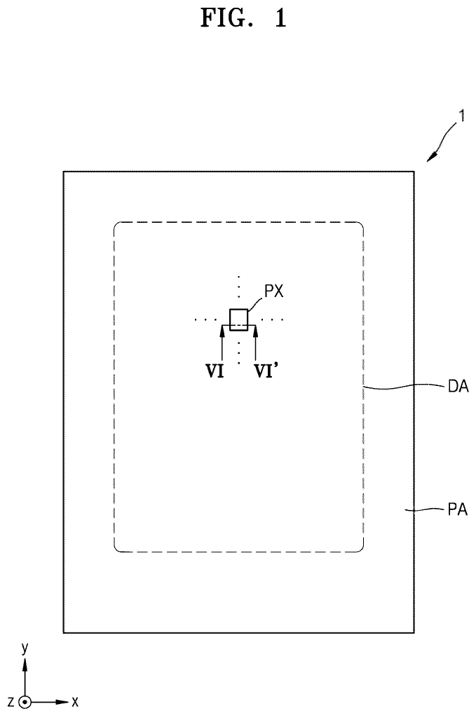

FIG. 1 is a plan view schematically illustrating a display apparatus 1 according to an embodiment of the present invention.

Referring to FIG. 1, the display apparatus 1 manufactured according to an embodiment of the present invention may include a display area DA and a peripheral area PA outside the display area DA. The display apparatus 1 may provide an image through an array of a plurality of pixels PX that are two-dimensionally arranged in the display area DA.

The peripheral area PA may be an area in which no image is provided, and may entirely or partially surround the display area DA. Drivers for providing electrical signals or power to each pixel circuit corresponding to each pixel PX may be arranged in the peripheral area PA. A pad, which is an area in which an electronic device or a printed circuit board may be electrically connected, may be arranged in the peripheral area PA.

Hereinafter, the case where the display apparatus 1 includes a light-emitting element, the display apparatus 1 may include an organic light-emitting diode (OLED), but the display apparatus 1 according to embodiments of the present invention is not limited thereto. In an embodiment of the present invention, the display apparatus 1 may be a light-emitting display apparatus including an inorganic light-emitting diode, e.g., an inorganic light-emitting display apparatus. The inorganic light-emitting diode may include a PN diode including materials based on an inorganic material semiconductor. When a voltage is applied to a PN junction diode in a forward direction, holes and electrons may be injected, and energy generated by re-combination of the holes and the electrons may be converted into light energy so that light having a certain color may be emitted. The above-described inorganic light-emitting diode may have a width of several to several hundreds of micrometers, and in embodiments of the present invention, the inorganic light-emitting diode may be referred to as a micro light-emitting diode (LED). In an embodiment of the present invention, the display apparatus 1 may be a quantum dot light-emitting display apparatus.

The display apparatus 1 may be applied to various products, such as mobile phones, smart phones, table personal computers (PCs), mobile communication terminals, electronic notes, electronic books, portable multimedia players (PMPs), navigation devices, ultra mobile PCs, televisions (TVs), laptop computers, monitors, billboards, Internet of Things (IoT), and the like. In addition, the display apparatus 1 according to an embodiment of the present invention may be used for a wearable device such as a smart watch, a watch phone, a glasses type display, or a head mounted display (HMD). In addition, the display apparatus 1 according to an embodiment of the present invention may be used as an instrument panel of a vehicle, a center information display (CID) display, which is disposed on a center fascia or a dashboard of a vehicle, a mirror display for replacing a side mirror of a vehicle, and a display screen for the rear seat or seats of the vehicle and is disposed on the rear surface of the front seat or another surface that faces the rear seats.

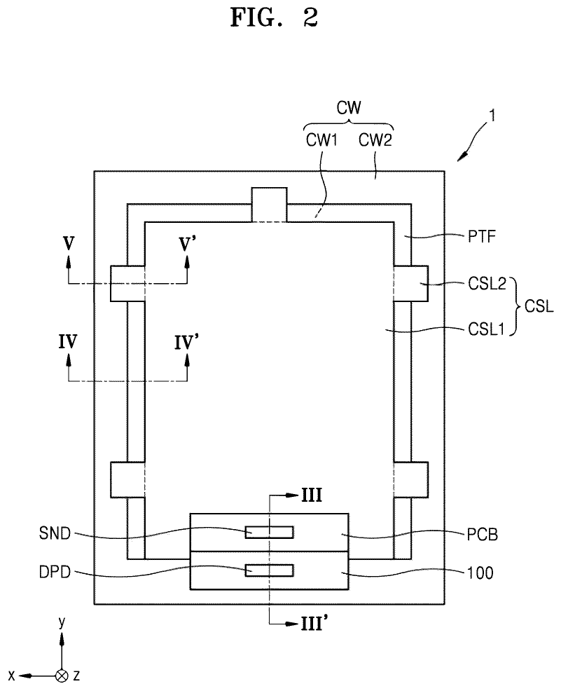

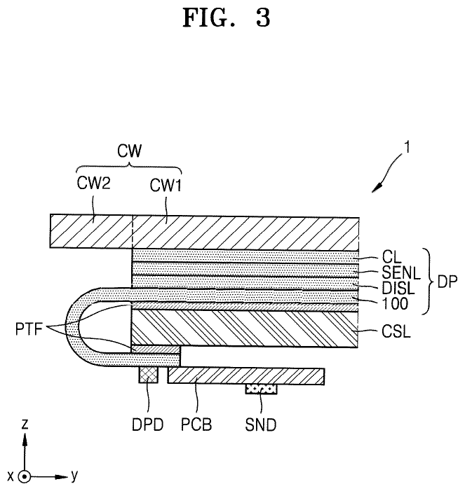

FIG. 2 is a rear view schematically illustrating part of the display apparatus 1 according to an embodiment of the present invention, and FIGS. 3 through 5 are cross-sectional views schematically illustrating part of the display apparatus 1 according to an embodiment of the present invention.

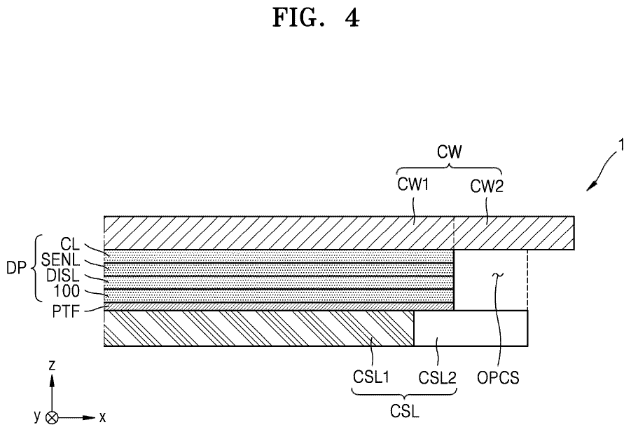

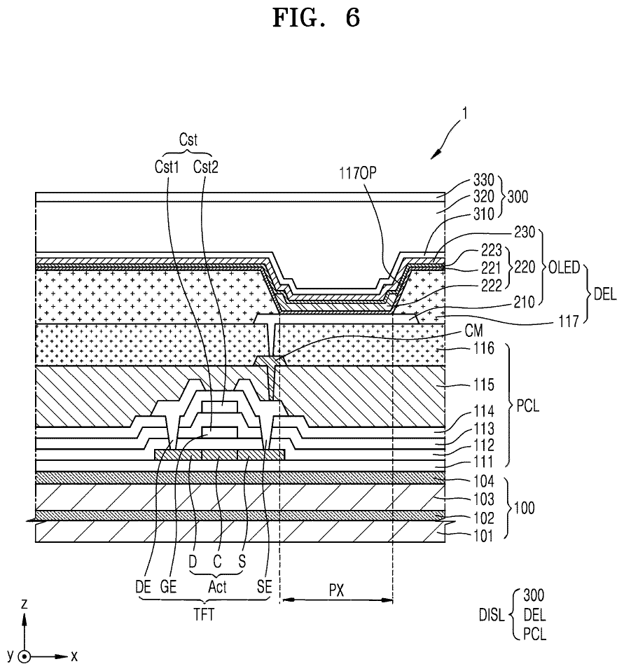

Specifically, FIG. 3 may correspond to a portion III-III′ of FIG. 2. FIG. 4 may correspond to a portion IV-IV′ of FIG. 2, and FIG. 6 may correspond to a portion V-V′ of FIG. 2.

Referring to FIGS. 2 through 5, the display apparatus 1 may include a display panel DP, a cover window CW, a protective film PTF, a cushion layer CSL, a printed circuit board PCB, a sensor driving portion SND, and a display driving portion DPD. Of course, the display apparatus 1 may further include a bracket or a main circuit board, or the like that is not shown.

The display panel DP may display (e.g., output) information that is to be processed by the display apparatus 1. For example, the display panel DP may display an execution or operation of an application, and the display panel DP may be driven by a driver. In addition, the execution or operation may be performed through the user interface (UI), and for example, a graphic user interface (GUI) information according to the execution or operation screen information may be provided. The display panel DP may include a substrate 100, a display layer DISL, a sensor electrode layer SENL, and a color filter layer CL.

The substrate 100 may include an insulating material such as glass, quartz, a polymer resin, or the like. The substrate 100 may be a rigid substrate 100 or a flexible substrate 100 that may be bent, folded or rolled. For your reference, FIG. 3 illustrates that only part of the substrate 100 is bent. However, the present invention is not limited thereto.

The display layer DISL may be arranged on the substrate 100 and may display images. The display layer DISL may be understood as a layer including display elements that are located on the substrate 100. For example, the display layer DISL may include a thin-film transistor layer, which includes thin-film transistors, a display element layer, which includes display elements such as an organic light-emitting device, and an encapsulation layer for encapsulating the display element layer.

The display elements may include, for example, a light emitting element. For example, the display panel DP may be an organic light-emitting display panel DP using an organic light-emitting diode including an organic light-emitting layer, a ultra-compact light-emitting diode display panel DP using a micro light-emitting diode (LED), a quantum dot light-emitting display panel DP using a quantum dot light-emitting diode including a quantum dot light-emitting layer, or an inorganic light-emitting display panel DP using an inorganic light-emitting device including an inorganic semiconductor.

The sensor electrode layer SENL may be arranged on the display layer DISL. The sensor electrode layer SENL may detect a user's touch input. The touch electrode layer SENL may detect a user's touch input by using at least one of various touch methods such as a resistive type method, a capacitive type method, and the like. Owing to the display layer DISL and the sensor electrode layer SENL, the display panel DP may function as an input device for providing an input interface between the display apparatus 1 and the user, and at the same time, an output device for providing an output interface between the display apparatus 1 and the user. A color filter layer CL may be arranged on the sensor electrode layer SENL. For example, color filter layer CL may be configured to reduce external light reflection; however, the present invention is not limited thereto.

The cover window CW may be arranged on the display panel DP. The cover window CW may cover an upper surface of the display panel DP. Thus, the cover window CW may protect the display panel DP.

The cover window CW may have a relatively high transmittance to transmit light emitted from the display panel DP, and may have a relatively thin thickness to minimize the weight of the display apparatus 1. In addition, the cover window CW may have a high strength and hardness to protect the display panel DP from external impact.

For example, the cover window CW may be a flexible window. The cover window CW may protect the display panel DP while being easily bent according to external force without occurrence of crack etc. For example, the cover window CW may include glass or plastic. For example, the cover window 30 may be ultra-thin tempered glass (UTG) that has been strengthened by methods such as chemical or thermal strengthening.

The cover window CW may include a first cover window portion CW1 and a second cover window portion CW2. The first cover window portion CW1 may overlap the protective film PTF and the display panel DP. The first cover window portion CW1 may be arranged in the center of the cover window CW.

The second cover window portion CW2 may at least partially surround the first cover window portion CW1. For example, the second cover window portion CW2 may be arranged outside the first cover window portion CW1. The second cover window portion CW2 might not overlap the protective film PTF and the display panel DP.

The protective film PTF may be arranged under the display panel DP. The protective film PTF may be attached to a rear surface of the substrate 100. The protective film PTF may include at least one of, for example, poly dimethylsiloxane (PDMS), thermoplastic polyurethane (TPU), and/or polyethylene terephthalate (PET).

The cushion layer CSL may be arranged under the protective film PTF. For example, part of the substrate 100 may be fixed onto an upper surface of the cushion layer CSL by the protective film PTF. The cushion layer CSL may absorb external shock to reduce damage of the display panel DP. The cushion layer CSL may have a single layer structure or a multi-layered structure.

Part of the substrate 100 may be bent and fixed onto a lower surface of the cushion layer CSL. The protective film PTF may be arranged between the lower surface of the cushion layer CSL and the substrate 100. Part of the substrate 100 may be arranged under the cushion layer CSL, and the protective film PTF may fix the lower surface of the cushion layer CSL and the substrate 100 to each other. For example, the protective film PTF may be attached to part the substrate 100, excluding a bending area of the substrate 100.

The printed circuit board PCB may be electrically connected to the display panel DP. The printed circuit board PCB may be fixed to the substrate 100. For example, the printed circuit board PCB may be electrically connected to the display panel DP through the substrate 100, which may include pads and circuitry that connect to the printed circuit board PCB and the display panel DP. For example, the printed circuit board PCB may be a flexible printed circuit board (FPCB) that may be bent, a rigid printed circuit board (PCB) that is hard and is not easily bent, or a composite PCB including both the rigid PCB and the FPCB.

The sensor driving portion SND may be arranged on the printed circuit board PCB. The sensor driving portion SND may include an integrated circuit. The sensor driving portion SND may be electrically connected to sensor electrodes of the sensor electrode layer SENL of the display panel DP through the printed circuit board PCB. The sensor driving portion SND may transmit sensor data to a main processor according to detected voltages, and the main processor may analyze the sensor data to calculate touch coordinates in which a touch input occurs.

The display driving portion (or a display driving circuit) DPD may be electrically connected to the display panel DP. The display driving portion DPD may be fixed to the substrate 100. For example, the display driving portion DPD may be electrically connected to the display panel DP through the substrate 100, which may include pads and circuitry that connect to the display driving portion DPD and the display panel DP. Control signals and power supply voltages may be applied to the display driving portion DPD, and the display driving portion DPD may generate signals and voltages for driving the display panel DP and output the signals and voltages. The display driving portion DPD may include an integrated circuit (IC).

Of course, pixels of the display panel DP, a scan driving unit (or a scan driving circuit), and a power supply unit (or a power supply circuit) for supplying driving voltages for driving the display driving portion DPD may be arranged on the printed circuit board PCB. In addition, the power supply unit may be integrated with the display driving portion DPD. In this case, the display driving portion DPD and the power supply unit may be formed of one IC.

The printed circuit board PCB may be electrically connected to a main printed circuit board PCB. For example, the main printed circuit board PCB may include a main processor, which includes an IC, a camera device, a wireless communication unit, an input unit, an output unit, an interface unit, a memory, a power supply unit, and/or the like.

Referring to FIGS. 2, 4, and 5, the cushion layer CSL may include a first cushion layer portion CSL1 and a second cushion layer portion CSL2.

The first cushion layer portion CSL1 may overlap the protective film PTF and the display panel DP. The first cushion layer portion CSL1 may be arranged in the center of the cushion layer CSL. The second cushion layer portion CSL2 may protrude outwards from the first cushion layer portion CSL1. At least part of the second cushion layer portion CSL2 might not be in contact with the protective film PTF and the display panel DP.

The second cover window portion CW2 and the second cushion layer portion CSL2 may be spaced apart from each other. A cushion opening OPCS may be arranged between the second cover window portion CW2 and the second cushion layer portion CSL2. For example, a thickness of the cushion opening OPCS may be substantially equal to a combined thickness of the display panel DP and the protective film PTF. Thus, a lower surface of the second cover window portion CW2 and an upper surface of the second cushion layer portion CSL2 may face each other.

The second cushion layer portion CSL2 may include a grounded metal material. Thus, when static electricity is introduced into the cover window CW, electrons may move to the second cushion layer portion CSL2, not the protective film PTF. Thus, a phenomenon that the protective film PTF and the substrate 100 are sequentially charged by static electricity, may be reduced. As a result, a phenomenon that a leakage current occurs in the display panel DP due to the protective film PTF and the substrate 100 being charged, may be reduced. Thus, the occurrence of a greenish phenomenon being displayed by the display apparatus 1 may be reduced.

For example, the second cushion layer portion CSL2 may include a copper material. The first cushion layer portion CSL1 and the second cushion layer portion CSL2 may include the same material as each other. For example, all of the first cushion layer portion CSL1 and the second cushion layer portion CSL2 may include a copper material and may be integrally provided. For example, the first cushion layer portion CSL1 and the second cushion layer portion CSL2 may be a single body. However, this is just an example, and the material for the first cushion layer portion CSL1 and the second cushion layer portion CSL2 is not limited thereto.

For example, the first cushion layer portion CSL1 and the second cushion layer portion CSL2 may include different materials from each other. For example, the first cushion layer portion CSL1, unlike the second cushion layer portion CSL2, may include at least one of polydimethylsiloxane (PDMS), thermoplastic polyurethane (TPU) and/or polyethylene terephthalate (PET), or may include a material having an elasticity such as a sponge molded with rubber, urethane material or acrylic material.

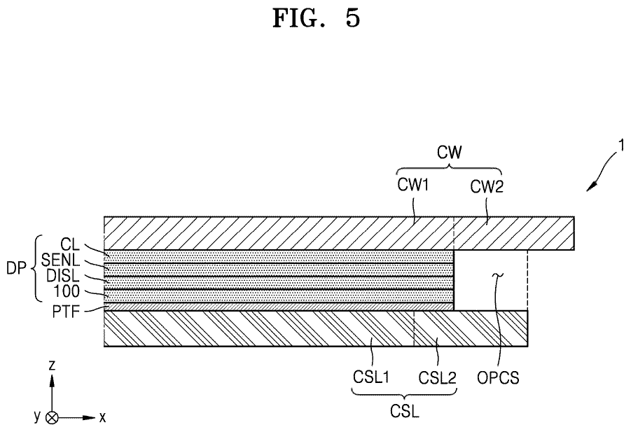

FIG. 6 is a cross-sectional view schematically illustrating the display apparatus 1 according to an embodiment of the present invention and may correspond to a cross-section of the display apparatus 1 taken along a line VII-VII′ of FIG. 5.

Referring to FIG. 6, the display apparatus 1 may include a substrate 100 and a display layer DISL. For example, the display layer DISL may include a stack structure that includes the pixel circuit layer PCL, the display element layer DEL, and the encapsulation layer 300.

The substrate 100 may have a multi-layered structure including a layer including the above-described polymer resin and an inorganic layer. For example, the substrate 100 may include a base layer including a polymer resin and a barrier layer including an inorganic insulating layer. For example, the substrate 100 may include a first base layer 101, a first barrier layer 102, a second base layer 103, and a second barrier layer 104, which are sequentially stacked. For example, each of the first base layer 101 and the second base layer 103 may include polyimide (PI), polyethersulfone (PES), polyarylate, polyetherimide (PEI), polyethylene naphthalate (PEN), polyethylene terephthalate (PET), polyphenylene sulfide (PPS), polycarbonate, cellulose triacetate (TAC) or/and cellulose acetate propionate (CAP). The first barrier layer 102 and the second barrier layer 104 may include an inorganic insulating material such as silicon oxide, silicon oxynitride and/or silicon nitride. The substrate 100 may have flexible characteristics.

The pixel circuit layer PCL may be arranged on the substrate 100. FIG. 6 illustrates that the pixel circuit layer PCL includes a thin-film transistor TFT, and a buffer layer 111, a first gate insulating layer 112, a second gate insulating layer 113, an interlayer insulating layer 114, a first planarization insulating layer 115, and a second planarization insulating layer 116, which are arranged on the substrate 100.

The buffer layer 111 may reduce or block penetration of foreign substances, moisture or external air from the lower portion of the substrate 100, and may provide a flat surface onto the substrate 100. The buffer layer 111 may include an inorganic insulating material such as silicon oxide, silicon oxynitride, or silicon nitride, and may have a single layer or a multi-layered structure including the above-described materials.

The thin-film transistor TFT that is disposed on the buffer layer 111 may include a semiconductor layer Act, and the semiconductor layer Act may include polysilicon (poly-Si). In addition, the semiconductor layer Act may include amorphous silicon (a-Si), an oxide semiconductor, or an organic semiconductor, etc. The semiconductor layer Act may include a channel region C, and a drain region D and a source region S, which are at opposing sides of the channel region C. A gate electrode GE may overlap the channel region C.

The gate electrode GE may include a low-resistance metal material. The gate electrode GE may include a conductive material including, for example, molybdenum (Mo), aluminum (AI), copper (Cu), titanium (Ti), or the like, and may have a multi-layered or single layer structure including the materials described above.

The first gate insulating layer 112 that is disposed between the semiconductor layer Act and the gate electrode GE may include an inorganic insulating material such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnOx). The zinc oxide (ZnOx) may be zinc oxide (ZnO) and/or peroxide (ZnO₂).

The second gate insulating layer 113 may be provided to cover the gate electrode GE. The second gate insulating layer 113 may include an inorganic insulating material such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnOx), similarly to the first gate insulating layer 112. The zinc oxide (ZnOx) may be zinc oxide (ZnO) and/or peroxide (ZnO₂).

An upper electrode Cst2 of a storage capacitor Cst may be arranged above the second gate insulating layer 113. The upper electrode Cst2 may overlap the gate electrode GE that is disposed under the upper electrode Cst2. At this time, the gate electrode GE and the upper electrode Cst2, which overlap each other with the second gate insulating layer 113 therebetween, may form the storage capacitor Cst. That is, the gate electrode GE may function as a lower electrode Cst1 of the storage capacitor Cst.

In this way, the storage capacitor Cst and the thin-film transistor TFT may overlap each other. In embodiments of the present invention, the storage capacitor Cst might not overlap the thin-film transistor TFT.

The upper electrode Cst2 may include, for example, aluminum (AI), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and/or copper (Cu), and may have a single layer or multi-layered structure including the materials described above.

The interlayer insulating layer 114 may be provided to cover the upper electrode Cst2. The interlayer insulating layer 114 may include an inorganic insulating material such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnOx). The zinc oxide (ZnOx) may be zinc oxide (ZnO) and/or peroxide (ZnO₂). The interlayer insulating layer 114 may have a single layer or multi-layered structure including the above-described inorganic insulating materials.

The drain electrode DE and the source electrode SE may be located on the interlayer insulating layer 114. The drain electrode DE and the source electrode SE may be connected to the drain region D and the source region S, respectively, through contact holes formed in insulating layers 112, 113, and 114 that are disposed under the drain electrode DE and the source electrode SE. The drain electrode DE and the source electrode SE may include a good conductive material. For example, each of the drain electrode DE and the source electrode SE may include a conductive material including molybdenum (Mo), aluminum (AI), copper (Cu), titanium (Ti), or the like, and may have a multi-layered or single layer structure including the materials described above. In an embodiment of the present invention, the drain electrode DE and the source electrode SE may have a multi-layered structure of Ti/Al/Ti.

The first planarization insulating layer 115 may cover the drain electrode DE and the source electrode SE. The first planarization insulating layer 115 may include an organic insulating material such as a general purpose polymer such as polymethylmethacrylate (PMMA) or polystyrene (PS), a polymer derivative having a phenol-based group, acryl-based polymer, imide-based polymer, aryl ether-based polymer, amide-based polymer, fluorine-based polymer, p-xylene-based polymer, vinyl alcohol-based polymer, and a combination thereof.

The second planarization insulating layer 116 may be arranged on the first planarization insulating layer 115. The second planarization insulating layer 116 may include the same material as the first planarization insulating layer 115, and may include an organic insulating material such as a general purpose polymer such as polymethylmethacrylate (PMMA) or polystyrene (PS), a polymer derivative having a phenol-based group, acryl-based polymer, imide-based polymer, aryl ether-based polymer, amide-based polymer, fluorine-based polymer, p-xylene-based polymer, vinyl alcohol-based polymer, and a combination thereof.

A display element layer DEL may be disposed on the pixel circuit layer PCL having the structure described above. The display element layer DEL may include an organic light-emitting diode OLED as a display element (e.g., a light-emitting device), and the organic light-emitting diode OLED may include a stack structure of a pixel electrode 210, an intermediate layer 220, and a common electrode 230. For example, the organic light-emitting diode OLED may emit red, green, or blue light, or may emit red, green, blue, or white light. The organic light-emitting diode OLED may emit light through an emission area, and the emission area may be defined as a pixel PX.

The pixel electrode 210 of the organic light-emitting diode OLED may be electrically connected to the thin-film transistor TFT through contact holes formed in the second planarization insulating layer 116 and the first planarization insulating layer 115 and a contact metal CM arranged on the first planarization insulating layer 115.

The pixel electrode 210 may include a transparent conductive oxide such as indium tin oxide (ITO), indium zinc oxide (IZO), zinc oxide (ZnO), indium oxide (In₂O₃), indium gallium oxide (IGO), or aluminum zinc oxide (AZO). In an embodiment of the present invention, the pixel electrode 210 may include a reflective layer including Ag, Mg, Al, Pt, Pd, Au, Ni, Nd, Ir, Cr, or a compound thereof. In an embodiment of the present invention, the pixel electrode 210 may further include layers formed of ITO, IZO, ZnO or In₂O₃ on/under the above-described reflective layer.

A bank layer 117 having an opening 117OP for exposing the center of the pixel electrode 210 may be arranged on the pixel electrode 210. The bank layer 117 may include an organic insulating material and an inorganic insulating material. The opening 117OP may define an emission area of light emitted from the organic light-emitting diode OLED. For example, the size/width of the opening 117OP may correspond to the size/width of the emission area. Thus, the size and/or width of the pixel PX may depend on the size and/or width of the opening 117OP of the bank layer 117.

The intermediate layer 220 may include a light-emitting layer 222 formed to correspond to the pixel electrode 210. The light-emitting layer 222 may include a polymer or a low molecular weight organic material emitting light of a certain color. In addition, the light-emitting layer 222 may include an inorganic light-emitting material or quantum dots.

In embodiments of the present invention, the intermediate layer 220 may include a first functional layer 221 and a second functional layer 223, which are arranged under and on the light-emitting layer 222. For example, the light emitting layer 222 may be arranged between the first functional layer 221 and the second functional layer 223. The first functional layer 221 may include, for example, a hole transport layer (HTL) or a HTL and a hole injection layer (HIL). The second functional layer 223 may be a component arranged above the light emitting layer 222 and may include an electron transport layer (ETL) and/or an electron injection layer (EIL). The first functional layer 221 and/or the second functional layer 223 may be a common layer formed to cover the substrate 100 similarly to the common electrode 230 to be described later. For example, the first functional layer 221 and/or the second functional layer 223 may entirely cover an upper surface of the substrate 100.

The common electrode 230 may be arranged on the pixel electrodes 210 and may overlap the pixel electrodes 210. The common electrode 230 may include a conductive material having a low work function. For example, the common electrode 230 may include a (semi-) transparent layer including Ag, Mg, Al, Pt, Pd, Au, Ni, Nd, Ir, Cr, Li, Ca or an alloy thereof. In addition, the common electrode 230 may further include a layer such as ITO, IZO, ZnO or In₂O₃ on the (semi-) transparent layer including the above-described materials. For example, the opposite electrode 230 may be integrally formed to cover the substrate 100 entirely.

The encapsulation layer 300 may be arranged on the display element layer DEL and may cover the display element layer DEL. The encapsulation layer 300 may include at least one inorganic encapsulation layer and at least one organic encapsulation layer, and in an embodiment of the present invention, FIG. 6 illustrates that the encapsulation layer 300 includes a first inorganic encapsulation layer 310, an organic encapsulation layer 320 and a second inorganic encapsulation layer 330, which are sequentially stacked.

For example, the first inorganic encapsulation layer 310 and the second inorganic encapsulation layer 330 may include one or more inorganic materials among aluminum oxide, titanium oxide, tantalum oxide, hafnium oxide, zinc oxide, silicon oxide, silicon nitride, and silicon oxynitride. The organic encapsulation layer 320 may include a polymer-based material. The polymer-based material may include an acryl-based resin, an epoxy-based resin, polyimide, polyethylene, or the like. In an embodiment of the present invention, the organic encapsulation layer 320 may include acrylate. The organic encapsulation layer 320 may be formed by hardening monomer or by coating polymer. The organic encapsulation layer 320 may have transparency.

A touch sensor layer may be arranged on the encapsulation layer 300, and an optical functional layer may be arranged on the touch sensor layer. The touch sensor layer may obtain coordinate information according to an external input, for example, a touch event. The optical functional layer may reduce reflectivity of light (e.g., external light) incident toward the display apparatus from the outside and/or may enhance color purity of light that is emitted from the display apparatus. In an embodiment of the present invention, the optical functional layer may include a phase retarder and/or a polarizer. The phase retarder may be of a film type or liquid crystal coating type and may include a N/2 phase retarder or a N/4 phase retarder. The polarizer may also be of a film type or liquid crystal coating type. The film type may include an elongation type synthetic resin film, and the liquid crystal coating type may include liquid crystals arranged in a certain arrangement. The phase retarder and the polarizer may further include a protective film.

An adhesive member may be arranged between the touch electrode layer and the optical functional layer. The adhesive member may be a general adhesive known in this technical field without restrictions. The adhesive member may be a pressure sensitive adhesive (PSA).

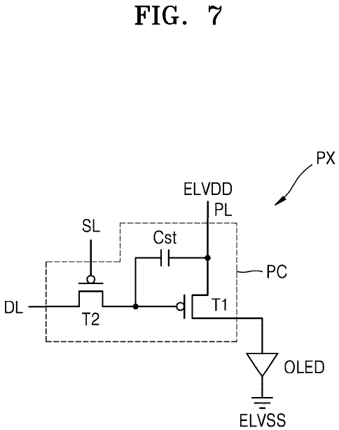

FIG. 7 is a circuit diagram of a pixel of the display apparatus 1 according to an embodiment of the present invention.

Each pixel PX may include a pixel circuit PC, a display element connected to the pixel circuit PC, for example, an organic light-emitting diode OLED. The pixel circuit PC may include a first thin-film transistor T1, a second thin-film transistor T2, and a storage capacitor Cst. Each pixel PX may emit, for example, red, green, blue, or white light through the organic light-emitting diode OLED.

The second thin-film transistor T2 may be a switching thin-film transistor, and may be connected to a scan line SL and a data line DL. In addition, the second thin-film transistor T2 may be configured to transmit a data voltage that is input from the data line DL in response to a switching voltage that is input from the scan line SL to the first thin-film transistor T1. The storage capacitor Cst may be connected to the second thin-film transistor T2 and a driving voltage line PL and may store a voltage corresponding to a difference between a voltage that is transmitted from the second thin-film transistor T2 and a first power supply voltage ELVDD that is supplied to the driving voltage line PL.

The first thin-film transistor T1 may be a driving thin-film transistor, and may be connected to the driving voltage line PL and the storage capacitor Cst. In addition, the first thin-film transistor T1 may control a driving current flowing through the organic light-emitting diode OLED from the driving voltage line PL in response to a voltage value that is stored in the storage capacitor Cst. The organic light-emitting diode OLED may emit light having certain luminance by using the driving current. An opposite electrode (e.g., a cathode) of the organic light-emitting diode OLED may receive a second power supply voltage ELVSS.

FIG. 7 illustrates the case where the pixel circuit PC includes two thin-film transistors and one storage capacitor, and the present invention is not limited thereto.

The number of thin-film transistors and the number of storage capacitors may be variously changed according to the design of the pixel circuit PC. For example, the pixel circuit PC may further include three, four, five or more thin-film transistors.

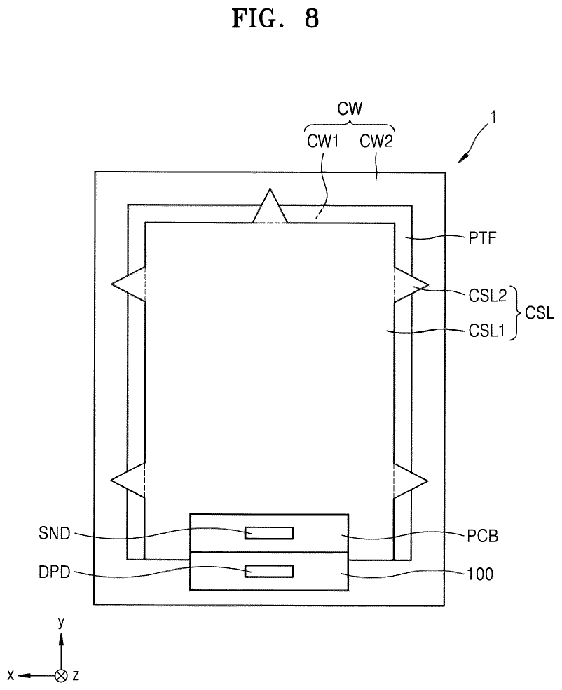

FIGS. 8 through 11 are rear views schematically illustrating the display apparatus 1 according to an embodiment of the present invention.

In FIGS. 8 through 11, the same reference numerals as those of FIGS. 2 through 5 represent same elements, and thus, redundant descriptions therewith are omitted or briefly discussed.

Referring to FIG. 2 and FIGS. 8 through 11, the second cushion layer portion CSL2 may have various shapes.

First, referring to FIG. 2 and FIGS. 8 through 10, the second cushion layer portion CSL2 may be provided in plurality. The plurality of second cushion layer portions CSL2 may be arranged to be spaced apart from each other along the perimeter or edge of the first cushion layer portion CSL1.

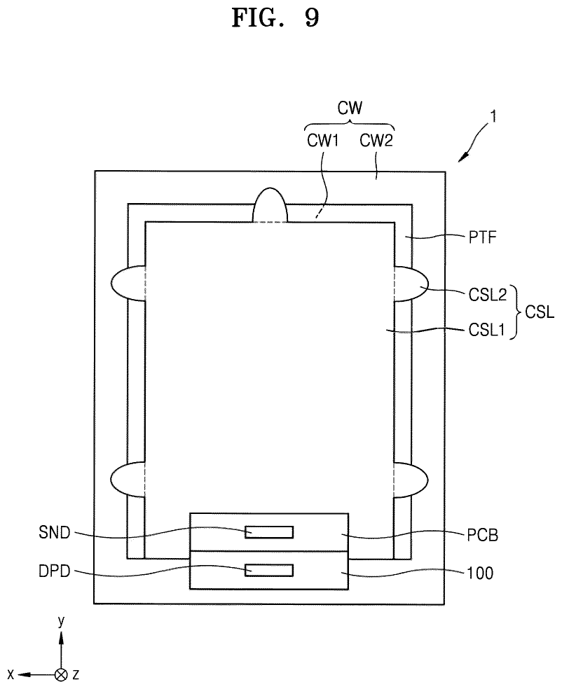

As shown in FIG. 2, on a plane, the second cushion layer portion CSL2 may have a rectangular shape, and as shown in FIG. 8, on a plane, the second cushion layer portion CSL2 may have a triangular shape, and as shown in FIG. 9, on a plane, the second cushion layer portion CSL2 may have part of an oval shape or curved shape.

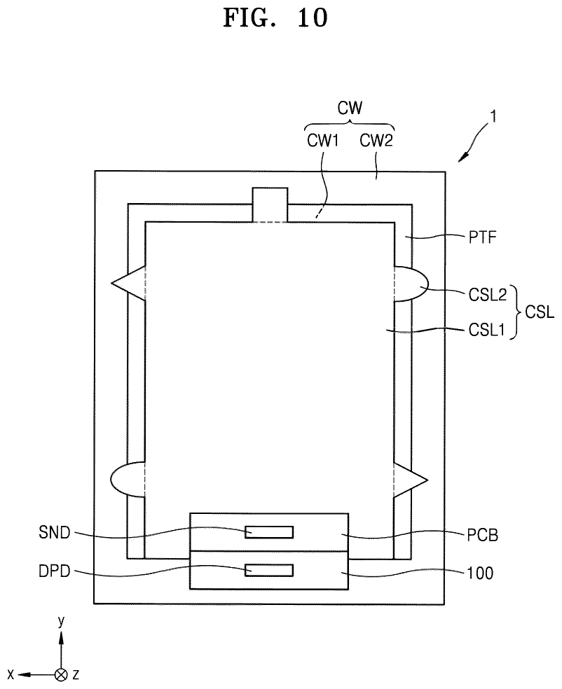

Also, as shown in FIG. 10, at least two shapes of the plurality of second cushion layer portions CSL2 may be different from each other. For example, on a plane, the second cushion layer CSL2 may have at least two of a rectangular shape, a triangular shape, and/or part of an oval shape.

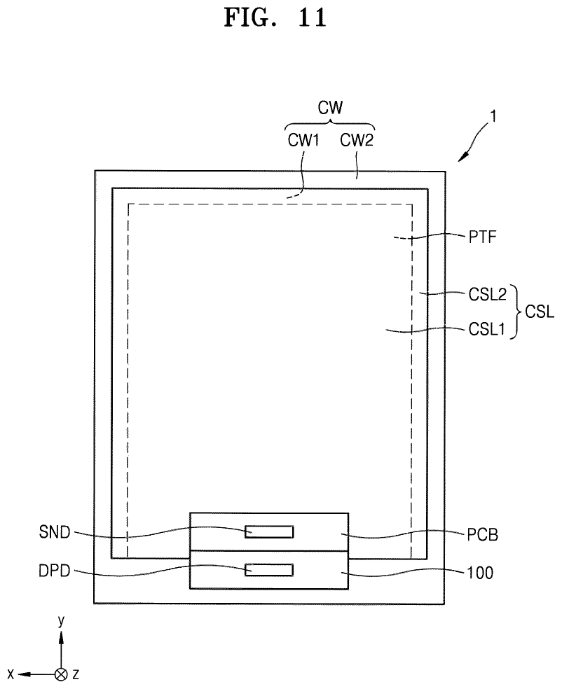

Referring to FIG. 11, the number of second cushion layer portions CSL2 may be one. The second cushion layer portions CSL2 may be arranged along the perimeter or edge of the first cushion layer portion CSL1. The second cushion layer portions CSL2 may surround at least part of the first cushion layer portion CSL1.

However, the shapes of the second cushion layer portion CSL2 shown in FIG. 2 and FIGS. 8 through 11 are examples, and the shape of the second cushion layer portion CSL2 is not limited thereto. The shape of the second cushion layer portion CSL2 may be variously designed in consideration of the shape of the display apparatus 1 or the like.

According to one or more embodiments of the present invention, the occurrence of a greenish phenomenon that is displayed due to a leakage current that is unintentionally generated in a display apparatus may be reduced.

The effects of the present invention are not limited to the aforementioned objectives, and other effects not mentioned can be clearly understood by a person of ordinary skill in the art from the present disclosure.

While the present invention has been described with reference to exemplary embodiments thereof, it will be understood by those of ordinary skill in the art that various changes in form and details may be made thereto without departing from the spirit and scope of the present invention.

What is claimed is:

1. A display apparatus comprising:
a display panel including a substrate and a display layer that is arranged on the substrate and that is configured to display images;
a cover window arranged on the display panel;
a protective film arranged under the display panel; and
a cushion layer arranged on the protective film,
wherein the cover window comprises:
a first cover window portion overlapping the protective film; and
a second cover window portion at least partially surrounding the first cover window portion,
wherein the cushion layer comprises:
a first cushion layer portion overlapping the protective film; and
a second cushion layer portion including a grounded metal material and protruding outwards from the first cushion layer portion, and
wherein the second cover window portion and the second cushion layer portion are spaced apart from each other.

2. The display apparatus of claim 1, wherein a cushion opening is arranged between the second cover window portion and the second cushion layer portion.

3. The display apparatus of claim 1, wherein at least part of the second cushion layer portion does not overlap the protective film.

4. The display apparatus of claim 1, wherein the first cushion layer portion and the second cushion layer portion comprise a same material as each other.

5. The display apparatus of claim 1, wherein the second cushion layer portion comprises a copper material.

6. The display apparatus of claim 1, wherein the second cushion layer portion is provided in a plurality.

7. The display apparatus of claim 6, wherein at least two of the plurality of second cushion layer portions have different shapes from each other.

8. The display apparatus of claim 1, wherein, on a plane, the second cushion layer portion has a rectangular shape.

9. The display apparatus of claim 1, wherein, on a plane, the second cushion layer portion has a triangular shape or part of an oval shape.

10. The display apparatus of claim 1, wherein the second cushion layer portion surrounds at least a part of the first cushion layer portion.

11. A display apparatus comprising:
a display panel including a substrate and a display layer that is arranged on the substrate and that is configured to display images;
a cover window arranged on the display panel;
a protective film arranged under the display panel; and
a cushion layer arranged under the protective film,
wherein the cover window comprises:
a first cover window portion overlapping the protective film; and
a second cover window portion at least partially surrounding the first cover window portion,
wherein the cushion layer comprises:
a first cushion layer portion overlapping the protective film; and
a second cushion layer portion including a grounded metal material and protruding outwards from the first cushion layer portion, and
wherein at least part of the second cushion layer portion does not overlap the protective film.

12. The display apparatus of claim 11, wherein the second cover window portion and the second cushion layer portion are spaced apart from each other.

13. The display apparatus of claim 11, wherein a cushion opening is arranged between the second cover window portion and the second cushion layer portion.

14. The display apparatus of claim 11, wherein the first cushion layer portion and the second cushion layer portion comprise a same material as each other.

15. The display apparatus of claim 11, wherein the second cushion layer portion comprises a copper material.

16. The display apparatus of claim 11, wherein the second cushion layer portion is provided in a plurality.

17. The display apparatus of claim 16, wherein at least two of the plurality of second cushion layer portions have different shapes from each other.

18. The display apparatus of claim 11, wherein, on a plane, the second cushion layer portion has a rectangular shape.

19. The display apparatus of claim 11, wherein, on a plane, the second cushion layer portion has a triangular shape or part of an oval shape.

20. The display apparatus of claim 11, wherein the second cushion layer portion surrounds at least a part of the first cushion layer portion.
